(19) United States
(12) Patent Application Publication
(10) Pub. No.: US 2024/0228190 A1
(43) Pub. Date: Jul. 11, 2024

(54) TRANSFER DEVICE AND EXPANSION AMOUNT CALCULATION METHOD

(71) Applicant: TOKYO ELECTRON LIMITED, Tokyo (JP)

(72) Inventors: Toshiaki KODAMA, Nirasaki-shi, Yamanashi (JP); Wataru MATSUMOTO, Nirasaki-shi, Yamanashi (JP)

(21) Appl. No.: 18/289,525

(22) PCT Filed: Aug. 11, 2021
(86) PCT No.: PCT/JP2021/029661

§ 371 Date: Nov. 3, 2023

(30) Foreign Application Priority Data
May 14, 2021 (JP) 2021-082040

(51) Int. Cl. B65G 47/90; H01L 21/677; H01L 21/687

(52) U.S. Cl. CPC B65G 47/905; H01L 21/677; H01L 21/68707

(57) ABSTRACT

In the present invention, an articulated arm is configured so that a plurality of arms are connected by rotatable joints, and by rotating the joints, the articulated arm can be extended and contracted. A detection unit detects the angle of rotation of the joints of the articulated arm, for different postures the number of which is at least the number of arms of the articulated arm. A calculation unit calculates the expansion amount of each of the plurality of arms on the basis of the angle of rotation of the joints at each of the postures detected by the detection unit.

### TECHNICAL FIELD

The present disclosure relates to a transfer device and an expansion amount calculation method.

### BACKGROUND

Patent Document 1 discloses a technique for determining thermal expansion of an arm of a transfer device at the time of automatically centering a substrate.

### PRIOR ART DOCUMENTS

### Patent Documents

Patent Document 1: Japanese Laid-open Patent Publication No. 2018-523307

### SUMMARY

### Problems to Be Resolved by the Invention

The present disclosure provides a technique for determining an expansion amount of each arm.

### Means for Solving the Problems

The transfer device according to an embodiment of the present disclosure comprises an articulated arm, a detector, and a calculator. The articulated arm includes a plurality of arms connected by rotatable joints, and is configured to be extensible and contractible by rotating the joints. T detector is configured to detect rotation angles of the joints of the articulated arm in different postures, the number of which is greater than or equal to the number of arms of the articulated arm. The calculator is configured to calculate an expansion amount of each of the arms based on the rotation angles of the joints in each posture detected by the detector.

### Effect of the Invention

In accordance with the present disclosure, the expansion amount of each arm can be determined.

### BRIEF DESCRIPTION OF THE DRAWINGS

FIG. 1 is a system configuration diagram showing an example of a processing system according to an embodiment.

FIG. 2 shows an example of a configuration of a robot arm according to an embodiment.

FIG. 3 shows an example of a cross section of a load-lock chamber and a vacuum transfer chamber according to an embodiment.

FIG. 4 explains an example of a method for specifying a center position of a substrate according to an embodiment.

FIG. 5 explains an example of detection of rotation angles of joints in different postures of an arm of the robot arm according to the embodiment.

FIG. 6 shows an example of the rotation angle of the joint of the robot arm according to the embodiment.

FIG. 7 explains a change in the rotation angle of the robot arm due to expansion of the arm according to the embodiment.

FIG. 8 is a system configuration diagram showing another example of the processing system according to the embodiment.

FIG. 9 shows an example of the rotation angle of the joint of the robot arm according to the embodiment.

FIG. 10 shows an example of the rotation angle of the joint of the robot arm according to the embodiment.

FIG. 11 explains an example of control flow of an expansion amount calculation method according to an embodiment.

FIG. 12 shows another example of a shape of a fork according to an embodiment.

FIG. 13 shows another example of the shape of the fork according to the embodiment.

FIG. 14 shows an example of a configuration of a tip end arm of the robot arm according to the embodiment.

FIG. 15 shows another example of a processing system main body according to an embodiment.

### DETAILED DESCRIPTION

Hereinafter, embodiments of a transfer device and an expansion amount calculation method of the present disclosure will be described in detail with reference to the accompanying drawings. The following embodiments are not intended to limit the transfer device and the expansion amount calculation method of the present disclosure.

A transfer device such as an articulated arm for transferring a substrate such as a semiconductor wafer (hereinafter, referred to as “wafer”) is known. The articulated arm has multiple arms connected by rotatable joints, and transfers the substrate supported by the arms.

Due to the influence of heat, an error may occur in the transfer position of the articulated arm. For example, when the articulated arm transfers a substrate to a process chamber for performing high-temperature substrate processing, each arm expands thermally due to the influence of heat, which may cause an error in the transfer position of the articulated arm.

Therefore, in order to suppress the error in the transfer position, a technique for obtaining an expansion amount of each arm is expected. In Patent Document 1, the thermal expansion of the entire articulated arm is determined, but the expansion amount of each arm is not obtained.

### Embodiment

### <Configuration of Processing System 1>

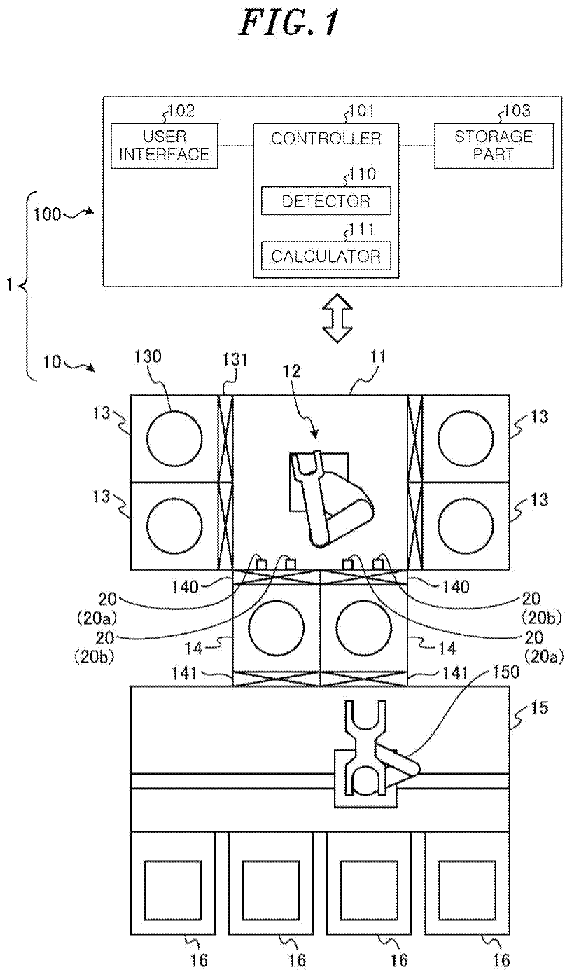

An embodiment will be described. Hereinafter, a processing system 1 including a function of a transfer device of the present disclosure will be described. FIG. 1 is a system configuration diagram showing an example of the processing system 1 according to an embodiment. In FIG. 1, the internal components of the apparatus are illustrated transparently for easier understanding. The processing system 1 performs substrate processing of a substrate such as a wafer or the like. The processing system 1 includes a processing system main body 10 and a controller 100 for controlling the processing system main body 10. The processing system main body 10 includes a vacuum transfer chamber 11, a plurality of process chambers 13, a plurality of load-lock chambers 14, and a loader module 15, as shown in FIG. 1, for example. The processing system 1 is an example of the transfer device of the present disclosure.

A plurality of the process chambers 13 and a plurality of the load-lock chambers 14 are connected to the vacuum transfer chamber 11. In the present embodiment, four process chambers 13 are connected to the vacuum transfer chamber 11. Further, two load-lock chambers 14 are connected to the vacuum transfer chamber 11. Three or less process chambers 13 may be connected to the vacuum transfer chamber 11, or five or more process chambers 13 may be connected to the vacuum transfer chamber 11. In addition to the process chambers 13, another vacuum transfer chamber 11 to which the process chambers 13 are connected may be additionally connected to the vacuum transfer chamber 11. Further, one load-lock chamber 14 may be connected to the vacuum transfer chamber 11, or three or more load-lock chambers 14 may be connected to the vacuum transfer chamber 11.

The process chamber 13 performs processing such as etching, film formation, or the like on a substrate in a low pressure environment, for example. The process chamber 13 and the vacuum transfer chamber 11 are partitioned by a gate valve 131 to be openable and closable. The process chamber 13 is an example of a chamber of the present disclosure. The process chambers 13 may be modules for performing the same process in the manufacturing process, or may be modules for performing different processes in the manufacturing process.

Each of the load-lock chambers 14 has a gate valve 140 and a gate valve 141, and a pressure therein is switched from a predetermined vacuum level to an atmospheric pressure, or from an atmospheric pressure to a predetermined vacuum level. The load-lock chamber 14 and the vacuum transfer chamber 11 are partitioned by the gate valve 140 so as to be openable and closable. Further, the load-lock chamber 14 and the loader module 15 are partitioned by the gate valve 141 to be openable and closable.

A plurality of sensors 20 are disposed in the vacuum transfer chamber 11. Further, a robot arm 12 is disposed in the vacuum transfer chamber 11. In the present embodiment, the robot arm 12 has three joints that can be driven independently. The robot arm 12 may have four or more joints that can be driven independently.

The inside of the vacuum transfer chamber 11 is maintained at a predetermined vacuum level. The robot arm 12 takes out unprocessed substrates from the load-lock chamber 14 of which pressure has been decreased to a predetermined vacuum level, and transfers them to placing tables 130 in some process chambers 13. Further, the robot arm 12 takes out a processed substrate from the process chamber 13 and transfers it into another process chamber 13 or the load-lock chamber 14.

Each sensor 20 is disposed near the connection portion between the vacuum transfer chamber 11 and the load-lock chamber 14. In the present embodiment, two sensors 20a and 20b are disposed, for each load-lock chamber 14, at a position near the connection portion between the vacuum transfer chamber 11 and the load-lock chamber 14 where the substrate W passes. Accordingly, when the substrate is taken out from the load-lock chamber 14 by the robot arm 12, the sensors 20a and 20b can quickly obtain sensing information on the substrate W. In present embodiment, two sensors 20 are provided for one load-lock chamber 14. Alternatively, three or more sensors 20 may be provided for one load-lock chamber 14.

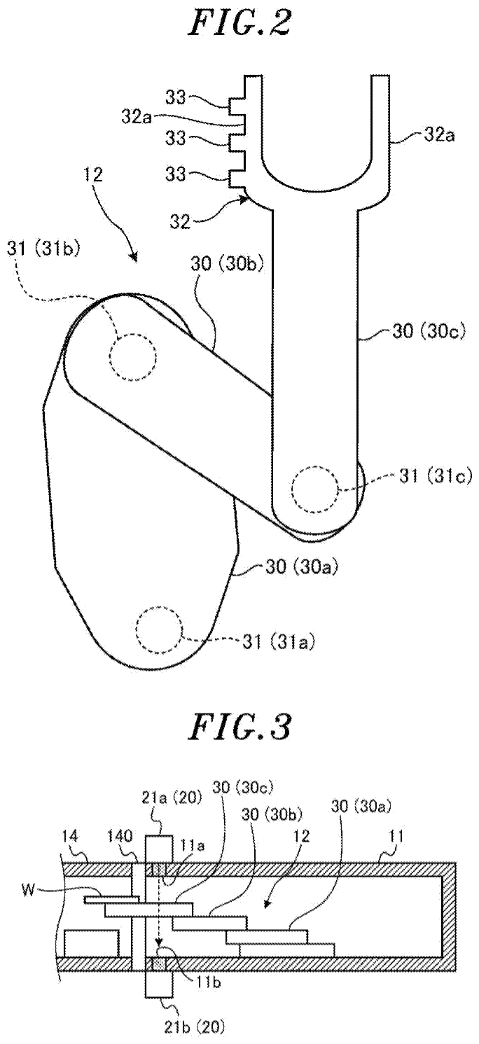

FIG. 2 shows an example of a configuration of the robot arm 12 according to the embodiment. The robot arm 12 is configured as an articulated arm in which a plurality of arms 30 are connected by rotatable joints 31 and can be extended and contracted by rotating the joints 31. For example, the robot arm 12 shown in FIG. 2 has arms 30a to 30c provided with joints 31a to 31c. The arms 30a and 30b are rotatably connected by the joint 31b, and the arms 30b and 30c are rotatably connected by the joint 31c. Each joint 31 is provided with a driving mechanism for rotating the joint 31, and the driving mechanism rotates the arms 30 in a horizontal direction. For example, each joint 31 is provided with the driving mechanism such as a servo motor, a speed reducer, or the like. Each joint 31 is rotated by a driving force of the servomotor transmitted via the speed reducer, thereby rotating the arms 30 in the horizontal direction. The rotation angle of each of the joints 31 of the robot arm 12 can be detected. For example, encoders are disposed at rotation shafts of the servo motors of the joints 31a to 31c, and the rotation angles of the joints 31a to 31c can be detected based on feedback signals from the encoders of the joints 31a to 31c.

The tip end arm 30c is provided with a Y-shaped fork 32 that branches into two support portions 32a on the tip end side. The fork 32 is made of a material with low thermal expansion, such as ceramic or the like. The robot arm 12 can be extended and contracted in the horizontal direction by rotating the arms 30 at the joints 31, and transfers the substrate W supported with the fork 32. The robot arm 12 has a shape that allows the sensor 20 to detect the extended/contracted position. For example, in the robot arm 12 shown in FIG. 2, one supporting portion 32a of the fork 32 is provided with three rectangular protrusions 33 that protrude in the horizontal direction.

FIG. 3 shows an example of a cross section of the load-lock chamber 14 and the vacuum transfer chamber 11 according to the embodiment. The sensor 20 has a light source 21a and a light receiving sensor 21b. The light source 21a and the light receiving sensor 21b are disposed outside the vacuum transfer chamber 11 to be located above and below the vacuum transfer chamber 11, respectively. In the present embodiment, the light source 21a is disposed above the vacuum transfer chamber 11, and the light receiving sensor 21b is disposed below the vacuum transfer chamber 11. However, the light source 21a may be disposed below the vacuum transfer chamber 11, and the light receiving sensor 21b may be disposed above the vacuum transfer chamber 11.

The light source 21a emits light into the vacuum transfer chamber 11 through a window 11a disposed at the upper wall of the vacuum transfer chamber 11. The light source 21a irradiates laser beam into the vacuum transfer chamber 11, for example. The light receiving sensor 21b receives light emitted from the light source 21a through a window 11b disposed at the lower wall of the vacuum transfer chamber 11. The windows 11a and 11b are made of a material that can transmit light, such as quartz or the like. The light receiving sensor 21b outputs, as sensing information, information indicating whether or not the light emitted from the light source 21a is blocked to the controller 100. The area irradiated with light from the light source 21a is an example of a sensing area.

Referring back to FIG. 1, the loader module 15 is connected to the load-lock chamber 14. A robot arm 150 is disposed in the loader module 15. The loader module 15 is provided with a plurality of load ports 16 to which containers (for example, front opening unified pod (FOUP)) capable of accommodating a plurality of unprocessed or processed substrates W are connected. The robot arm 150 takes out an unprocessed substrate W from the container connected to the load port 16 and transfers it into the load-lock chamber 14. Further, the robot arm 150 takes out a processed substrate W from the load-lock chamber 14 of which pressure has been returned to the atmospheric pressure, and transfers it into the container connected to the load port 16. The loader module 15 may be provided with an alignment unit for adjusting the orientation of the substrate W taken out from the container connected to the load port 16.

The operation of the processing system 1 configured as described above is collectively controlled by the controller 100 (control part). The controller 100 is, for example, a computer, and controls individual components of the processing system 1. The operation of the processing system 1 is collectively controlled by the controller 100.

The controller 100 includes a controller 101 for controlling individual components of the processing system 1, a user interface 102, and a storage part 103.

The user interface 102 includes a keyboard through which a process manager inputs commands to manage the processing system 1, a display for visualizing and displaying an operation status of the processing system 1, and the like.

The storage part 103 stores control programs (software) for realizing various processes executed by the processing system 1 under the control of the controller 101, or recipes in which processing condition data and the like are stored. Further, the storage part 103 stores parameters and the like related to devices or processes for substrate processing. The control programs, the recipes, and the parameters may be stored in a computer-readable computer recording medium (for example, a hard disk, an optical disk such as a DVD, a flexible disk, a semiconductor memory, or the like). Further, the control programs, the recipes, and the parameters may be stored in another device and read out and used online through a dedicated line, for example.

The controller 101 has a CPU and an internal memory for storing programs or data, reads the control program stored in the storage part 103, and executes processing of the read control program. The controller 101 functions as various processing units by executing the control programs. For example, the controller 101 has functions of a detector 110 and a calculator 111 to be described later. In the present embodiment, a case where the controller 101 functions as various processing parts will be described as an example, but the present disclosure is not limited thereto. For example, the functions of the detector 110 and the calculator 111 may be distributed and realized by a plurality of controllers.

### <Method for Specifying Center Position of Substrate>

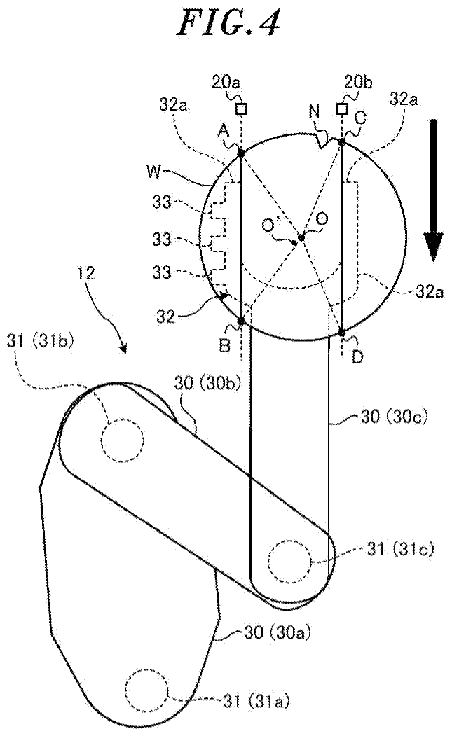

Next, a method for specifying the center position of the substrate W will be described. FIG. 4 explains an example of a method for specifying the center position of the substrate W according to an embodiment. When the substrate W is taken out from the load-lock chamber 14 by the robot arm 12, the sensors 20a and 20b output the sensing information to the controller 100. When the substrate W on the fork 32 at the tip end of the robot arm 12 passes through the sensing area, the light emitted from the light source 21a is blocked at line segments AB and CD on the substrate, as indicated by the solid line of FIG. 4. The controller 100 specifies the center of the circle passing through at least three points among the points A to D as a center position O of the substrate W based on the sensing information outputted from the sensors 20a and 20b and the position information of the fork 32. The position information of the fork 32 is specified based on, for example, the lengths of the arms 30 of the robot arm 12, the angles of the joints 31, and the like. The angles of the joints 31 are detected based on feedback signals from the encoders of the joints 31a to 31c. In the example of FIG. 4, the center position O of the substrate W and a reference position O′ of the fork 32 do not coincide with each other.

Depending on the position or the orientation of the substrate W with respect to the fork 32, the notch N of the substrate W may pass through the sensing area when the substrate W moves, or the light may be blocked by the fork 32. In this case, the position of the center of the circle passing through all the points A to D may not coincide with the center position O of the substrate W, or the circle passing through all the points A to D may not exist. Therefore, when the distance between the center positions of the circles calculated in two or more combinations among four combinations of three points except one of the points A to D is smaller than a predetermined distance, it is preferable to specify the center position as the center position O of the substrate W. The notch N formed at the substrate W is an example of a marker indicating the reference direction of the substrate W. The marker indicating the reference direction of the substrate W may be an orientation flat formed at the substrate W.

### <Method for Calculating Expansion Amount of Arm>

Next, a method for calculating an expansion amount of each of the arms 30 of the robot arm 12 will be described. The processing system 1 detects the rotation angles of the joints 31 of the robot arm 12 in different postures, the number of which is greater than or equal to the number of arms of the robot arm 12.

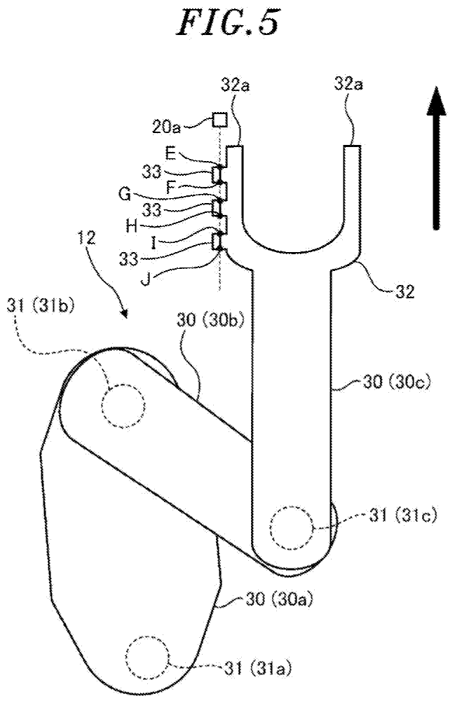

FIG. 5 explains an example of detection of the rotation angles of the joints 31 in different postures of the arms 30 of the robot arm 12 according to the embodiment. For example, the controller 100 moves the robot arm 12 such that the protrusions 33 disposed at the fork 32 pass through the position where the sensor 20a is disposed. When the robot arm 12 is moved such that the protrusions 33 pass through the position where the sensor 20a is disposed, the rotation angles of the joints 31 change to extend the entire robot arm 12, so that the posture of each of the arms 30 is changed. The sensor 20a outputs the sensing information to the controller 100. The robot arm 12 outputs the feedback signals from the encoders of the joints 31 to the controller 100. When the protrusions 33 disposed at the fork 32 pass through the sensing area, the light emitted from the light source 21a is blocked at line segments EF, GH, and IJ of the protrusions 33, as indicated by the solid line of FIG. 5.

The detector 110 detects the rotation angles of the joints 31 of the robot arm 12 based on the feedback signals from the encoders of the joints 31. The feedback signals of the encoders of the joints 31 may be inputted to the controller for controlling the robot arm 12, and the controller may specify the angles of the joints 31. The detector 110 may detect the rotation angles of the joints 31 by obtaining the rotation angles of the joints 31 from the controller of the robot arm 12.

The detector 110 detects the rotation angles of the joints 31 of the robot arm 12 in different postures, the number of which is greater than or equal to the number of arms 30 of the robot arm 12. In present embodiment, the detector 110 detects the rotation angles of the joints 31 in different postures based on the sensing information outputted from the sensor 20a and the information on the rotation angles of the joints of the robot arm 12. For example, the detector 110 detects the rotation angles of the joints 31a to 31c at points E, G, and I where the light emitted from the light source 21a is blocked by the protrusions 33.

FIG. 6 shows an example of the rotation angles of the joints 31 of the robot arm 12 according to the embodiment. The detector 110 determines an axis 60 passing through a reference point on a horizontal plane with the position where the robot arm 12 is fixed as the reference point, and detects the rotation angles of the joints 31 from the axis 60. The direction of the axis 60 may be predetermined when the processing system 1 is designed.

If the rotation angle of a joint 31 is not with respect to the axis 60, the detector 110 corrects it to the rotation angle with respect to the axis 60. For example, when the rotation angle of the joint 31a is a rotation angle ϕ1 with respect to another axis 61, the rotation angle θ1 of the joint 31a is corrected as shown in the following Eq. (1).

$$θ1 = ϕ1 + α \qquad ( 1 )$$

Here, θ1 indicates the rotation angle of the arm 30a with respect to the axis 60.

ϕ1 indicates the rotation angle of the arm 30a with respect to the axis 61.

α indicates the angle difference between the axis 60 and the axis 61 with respect to the axis 60.

For example, when the rotation angle of the joint 31b is a rotation angle ϕ2 of the arm 30a with respect to the direction of the arm 30a, the rotation angle θ2 of the joint 31b is corrected as shown in the following Eq. (2).

$$θ3 = ϕ2 + ϕ1 = ϕ2 + ϕ1 + α \qquad ( 2 )$$

Here, θ2 indicates the rotation angle of the arm 30b with respect to the axis 60.

ϕ2 indicate the rotation angle of the arm 30b with respect to the direction of the arm 30a.

For example, when the rotation angle of the joint 31c is a rotation angle ϕ3 of the arm 30b with respect to the direction of the arm 30b, the rotation angle θ3 of the joint 31c is corrected as shown in the following Eq. (3).

$$θ3 = ϕ3 + 02 = ϕ3 + ϕ2 + ϕ1 + α \qquad ( 3 )$$

Here, θ3 indicates the rotation angle of the arm 30c with respect to the axis 60. ϕ3 indicates the rotation angle of the arm 30c with respect to the direction of the arm 30b.

The detector 110 detects each of the rotation angles θ1 to 03 of the joints 31 at each of the points E, G, and I where the light emitted from the light source 21a is blocked by the protrusions 33.

When the arms 30 of the robot arm 12 are expanded, the rotation angles θ1 to 03 change. The controller 100 moves the robot arm 12 such that the protrusions 33 disposed at the fork 32 pass through the position where the sensor 20a is disposed. When the robot arm 12 is moved such that the protrusions 33 pass through the position where the sensor 20a is disposed, the rotation angles of the joints 31 change to extend the entire robot arm 12, so that the postures of the arms 30 is changed. The sensor 20a outputs the sensing information to the controller 100. The robot arm 12 outputs the feedback signals of the encoders of the joints 31 to the controller 100. When the protrusions 33 disposed at the fork 32 pass through the sensing area, the light emitted from the light source 21a is blocked at the line segments EF, GH, and IJ of the protrusions 33, as indicated by the solid line of FIG. 5, for example.

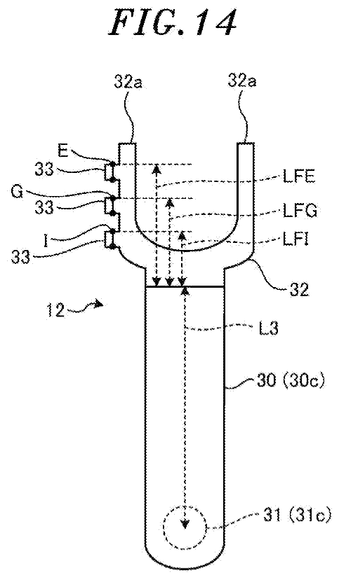

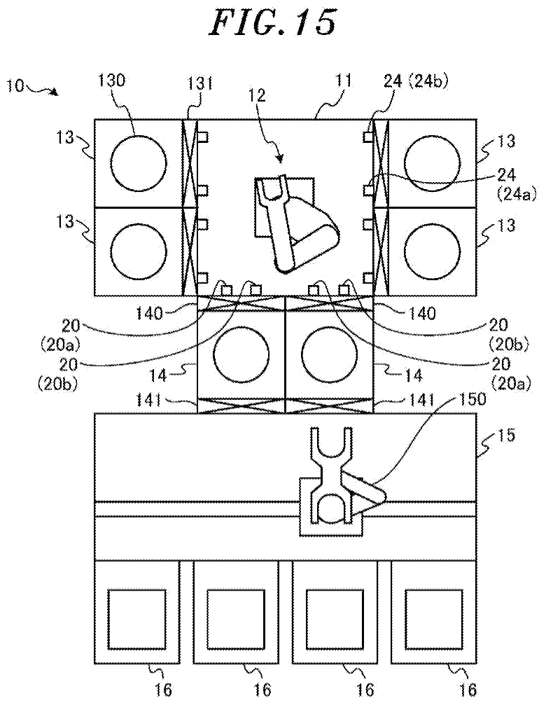

Here, in the robot arm 12 of the present embodiment, the arm 30c is provided with the fork 32 made of a material with low thermal expansion. FIG. 14 shows an example of the configuration of the tip end arm 30c of the robot arm 12 according to the embodiment. FIG. 14 shows the tip end arm 30c of the robot arm 12. The fork 32 is connected at the tip end side of the tip end arm 30c. FIG. 14 shows a distance LFE from the connection portion between the arm 30c and the fork 32 to the point E, a distance LFG from the connection portion to the point G, a distance LFI from the connection portion to the point I, and a length L3 of the arm 30c. The fork 32 is made of a material with low thermal expansion. Therefore, even if a temperature changes in the arm 30c, the distances LFE, LFG, and LFI of the fork 32 hardly change, and the length L3 of the arm 30c changes mainly.

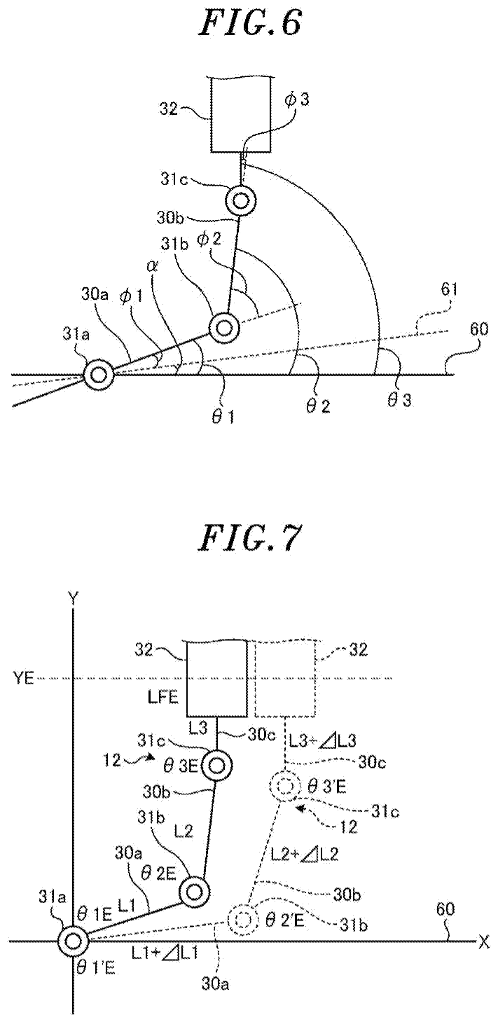

FIG. 7 explains a change in the rotation angle due to the expansion of the arms 30 of the robot arm 12 according to the embodiment. FIG. 7 shows a change in the rotation angle at the point E where the light emitted from the light source 21a is blocked by the protrusions 33 in a state where the axis 60 is set to the X-axis and the direction perpendicular to the axis 60 on the horizontal plane is set to the Y-axis. In FIG. 7, the robot arm 12 in a non-expansion state where the arms 30 are not expanded is schematically indicated by a solid line, and the robot arm 12 in an expansion state where the arms 30 are expanded is schematically indicated by a dashed line.

A distance Y of the robot arm 12 in the Y-axis direction can be calculated from the lengths of the arms 30, the rotation angles of the joints 31, or the like. For example, the lengths of the arms 30a to 30c of the robot arm 12 in a state where the arms 30 are not expanded are set to L1 to L3, respectively. Further, as indicated by the solid line of FIG. 7, the rotation angles of the joints 31 at the point E where the light emitted from the light source 21a is blocked by the protrusions 33 in a state where the arms 30 are not expanded are set to θ1E to θ3E. In this case, a distance YE of the point E in the Y-axis direction can be expressed by the following Eq. (4).

$$YE = L 1 \cdot sin θ1 E + L 2 \cdot sin θ2 E + ( L 3 + LFE ) \cdot sin θ3 E \qquad ( 4 )$$

Here, YE indicates the distance of the point E in the Y-axis direction.

L1 to L3 indicate the lengths of the arms 30a to 30c in the non-expansion state.

LFE indicates the distance from the connection portion between the fork 32 and the arm 30c to the position of the point E.

θ1E to θ3E respectively indicate the rotation angles of the joints 31a to 31c at the point E in the non-expansion state.

For example, the lengths of the arms 30a to 30c described in the specifications of the robot arm 12, or the lengths of the arms 30a to 30c at room temperature are used as the lengths L1 to L3 of the arms 30a to 30c of the robot arm 12 in a non-expansion state.

On the other hand, the expansion amounts in the length direction of the arms 30a to 30c of the robot arm 12 in a state where the arms 30 are expanded are set to ΔL1 to ΔL3, respectively. As indicated by the dashed line of FIG. 7, the rotation angles of the joints 31 at the point E where the light emitted from the light source 21a is blocked by the protrusions 33 in a state where the arms 30 are expanded are respectively set to θ1′E to θ3′E. In this case, the distance YE of the point E in the Y-axis direction can be expressed by the following Eq. (5). The fork 32 is made of a material with low thermal expansion, and the length change due to thermal expansion hardly occurs. The expansion amount of the fork 32 may be included in the expansion amount ΔL3 of the arm 30c in the length direction. Further, the distance LFE of the fork 32 is included in the arm 30c, and thus may be omitted from Eqs. (4) and (5).

$$YE = ( L 1 + Δ L 1 ) \cdot sin {θ1}^{′} E + ( L 2 + Δ L 2 ) \cdot sin {η2}^{′} E + ( L 3 + Δ L 3 + LFE ) \cdot in {θ3}^{′} E \qquad ( 5 )$$

Here, ΔL1 to ΔL3 indicate the expansion amounts of the lengths of the arms 30a to 30c, respectively.

θ1′E to θ3′E indicate the rotation angles of the joints 31a to 31c at the point E in an expansion state, respectively.

The distance YE of the point E in the Y-axis direction, the lengths L1 to L3 of the arms 30 in a non-expansion state, and the distance LFE of the fork 32 are determined from the actual measurement of the processing system 1 or the design data of the processing system 1. The distance YE may be calculated from the lengths L1 to L3 of the arms 30 in a non-expansion state and the rotation angles θ1 to θ3 of the joints 31 using Eq. (4).

The detector 110 detects each of the rotation angles θ1 to θ3 of the joints 31 at each of the points E, G, and I where the light emitted from the light source 21a is blocked by the protrusions 33. Here, when the arms 30 of the robot arm 12 are expanded, the rotation angles θ1 to θ3 detected by the detector 110 respectively become rotation angles θ1′ to θ3′. For example, at the point E, as shown in FIG. 7, when the arms 30 of the robot arm 12 are not expanded, the rotation angles θ1E to θ3E are detected by the detector 110. On the other hand, when the arms 30 of the robot arm 12 are expanded, the rotation angles θ1′E to θ3′E are detected by the detector 110. Further, at the point G, when the arms 30 of the robot arm 12 are not expanded, rotation angles θ1G to θ3G are detected by the detector 110. On the other hand, when the arms 30 of the robot arm 12 are expanded, rotation angles θ1′G to θ3′G are detected by the detector 110. Further, at the point I, when the arms 30 of the robot arm 12 are not expanded, rotation angles θ1I to θ3I are detected by the detector 110. On the other hand, when the arms 30 of the robot arm 12 are expanded, rotation angles θ1′I to θ3′I are detected by the detector 110.

In Eq. (5), the distance YE and the lengths L1 to L3 of the arms 30 are determined from the actual measurement of the processing system 1 and the design data of the processing system 1. Further, the rotation angles θ1′E to θ3′E are detected by the detector 110. Therefore, in Eq. (5), unknown values are the expansion amounts ΔL1 to ΔL3 of the arms 30.

Three Eqs. (5) for the distance YE of the point E in the Y-axis direction, the distance YG of the point G in the Y-axis direction, and the distance YI of the point I in the Y-axis direction can be obtained from the rotation angles θ1′ to θ3′ of the joints 31 at the points E, G, and I, respectively. For example, the distance YG of point G in the Y-axis direction can be obtained by replacing the distance LFE of Eq. (5) with the distance LFG from the connection portion with the arms 30c of the fork 32 to the position of point G, and replacing the rotation angles θ1′E to θ3′E with the rotation angles θ1′G to θ3′G. Further, the distance YI of the point I in the Y-axis direction can be obtained by replacing the distance LFE of Eq. (5) with the distance LFI from the connection portion with the arm 30c of the fork 32 to the position of the point I, and replacing the rotation angles θ1′I to θ3′I with the rotation angles θ1′G to θ3′G. The distances YG and YI, and the distances LFG and LFI are determined from the actual measurement of the processing system 1 and the design data of the processing system 1. The distances LFE, LFG, and LFI are included in the arm 30c, and thus may be omitted from Eq. (5). Since three expansion amounts ΔL1 to ΔL3 are unknown values in Eq. (5), the expansion amounts ΔL1 to ΔL3 can be calculated by solving the equation using the expansion amounts ΔL1 to ΔL3 as unknown values from three Eqs. (5).

Although Eq. (5) has been described using the relationship at the point E as an example, Eq. (5) is a relational expression showing the relationship between the extended/contracted distance Y (YE) of the robot arm 12, the lengths L1 to L3 of the arms 30 in a non-expansion state, the rotation angles θ1′ to θ3′ (θ1′E to θ3′E) of the joints 31, and the expansion amounts ΔL1 to ΔL3 of the lengths of the arms 30.

The calculator 111 applies, to Eq. (5), the extended/contracted distance Y of the robot arm 12 and the rotation angles θ1′ to θ3′ of the joints 31 detected by the detector 110 in each posture. Then, the calculator 111 calculates the expansion amounts ΔL1 to ΔL3 by solving the equation using the expansion amounts ΔL1 to ΔL3 in Eq. (5) in each posture as unknown values.

In accordance with the present embodiment, the expansion amounts ΔL1 to ΔL3 of the arms 30 can be obtained in the above-described manner.

When the robot arm 12 transfers the substrate W, the controller 100 corrects the transfer position of the robot arm 12 based on the expansion amounts of the arms 30 calculated by the calculator 111. For example, the controller 100 corrects the rotation angles of the joints 31a to 31c while considering the increase in the lengths of the arms 30a by the expansion amounts ΔL1 to ΔL3. Accordingly, even when the arms 30 are expanded due to the influence of heat, the error in the transfer position of the robot arm 12 can be suppressed.

The calculator 111 may calculate the expansion amounts of the arms 30 in the following manner. For example, three Eqs. (5) for three postures can be transformed into three Eqs. (5) using the expansion amounts ΔL1 to ΔL3 as solutions. The transformed three equations are relational expressions for calculating the expansion amounts ΔL1 to ΔL3 of the arms 30 from the extended/contracted distance Y (YE, YG, YI) of the robot arm 12 in each posture, the lengths L1 to L3 of the arms 30 that are not expanded, and the rotation angles θ1′ to θ3′ of the joints 31 in each posture. The relational expressions for calculating the expansion amounts ΔL1 to ΔL3 of the arms 30 are preset in the calculator 111. For example, the relational expressions are programmed in the calculator 111. The calculator 111 calculates the expansion amounts ΔL1 to ΔL3 of the arms 30 by applying the rotation angles θ1′ to θ3′ of the joints 31 in each posture detected by the detector 110, to the set relational expressions. In this case as well, each of the expansion amounts ΔL1 to ΔL3 of each of the arms 30 can be obtained.

In the above-described embodiment, the case of calculating the expansion amounts ΔL1 to ΔL3 of the arms 30 from the rotation angles θ1′ to θ3′ of the joints 31 in three postures same as those of the arms 30 of the robot arm 12 has been described as an example. However, the rotation angles θ1′ to θ3′ of the joints 31 may be detected in four or more postures. For example, four or more protrusions 33 may be disposed at one support portion 32a of the fork 32, and the rotation angles θ1′ to θ3′ of the joints 31 may be detected in four or more postures where the protrusions 33 pass through the arrangement position of the sensor 20a. Further, the rotation angles θ1′ to θ3′ of the joints 31 in four or more postures where the protrusions 33 pass may be detected at the positions of the two sensors 20a and 20b disposed near the connecting portion between the vacuum transfer chamber 11 and the load-lock chamber 14.

When the rotation angles θ1′ to θ3′ of the joints 31 are detected in four or more postures, the calculator 111 calculates the expansion amounts of the arms 30 from the rotation angles θ1′ to θ3′ of the joints 31 for combination of three postures selected among four or more postures. The calculator 111 calculates averages of the expansion amounts of the arms 30 as the expansion amounts ΔL1 to ΔL3 of the arms 30. By calculating the expansion amounts of the arms 30, the accuracy of the expansion amounts ΔL1 to ΔL3 can be improved.

In the above-described embodiment, the case where one sensor 20 detects multiple postures of the robot arm 12 has been described as an example. However, multiple sensors 20 may detect multiple postures of the robot arm 12. For example, the sensors 20 may be disposed at different positions, the number of which is greater than or equal to the number of arms 30 of the robot arm 12, and the detector 110 may detect the rotation angles θ1′ to θ3′ of the joints 31 in postures where the tip end of one support portion 32a of the fork 32 is detected by the sensors 20.

The sensor 20 is not necessarily disposed near the connecting portion between the vacuum transfer chamber 11 and the load-lock chamber 14. The sensor 20 may be disposed at any position as long as it is accessible by the robot arm 12 and the arrangement position of the sensor 20 is less likely to change due to the influence of heat or the like. For example, the sensor 20 may be disposed anywhere in the vacuum transfer chamber 11.

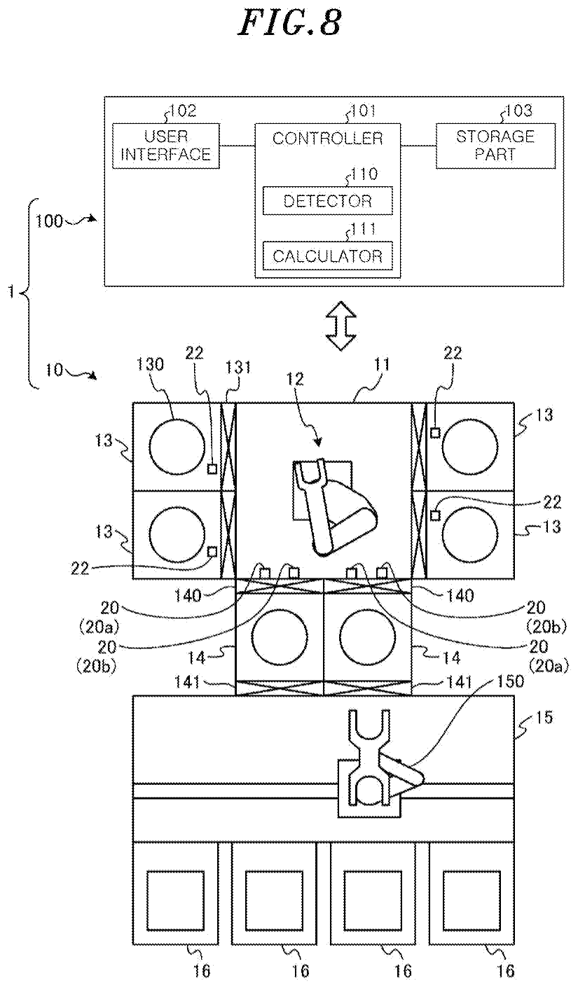

In the case of processing a substrate at a high temperature, the process chamber 13 may thermally expand in the horizontal direction. Therefore, the expansion amount of the process chamber 13 may be detected using the technique of the present disclosure. FIG. 8 is a system configuration diagram showing another example of the processing system according to the embodiment. In FIG. 8, like reference numerals will be used for like parts as those of FIG. 1, and redundant description thereof will be omitted. In the processing system 1 shown in FIG. 8, a sensor 22 that is the same as the sensor 20 is disposed in the process chamber 13.

The detector 110 detects the rotation angles of the joints 31 when the robot arm 12 is detected by the sensor 22 disposed in the process chamber 13. For example, in the case of detecting the expansion amount of the process chamber 13, the controller 100 moves the robot arm 12 such that the protrusions 33 disposed at the fork 32 pass through the arrangement position of the sensor 22 disposed in the process chamber 13. The detector 110 detects the rotation angles of the joints 31 at the time of detecting the protrusions 33 of the robot arm 12. For example, the detector 110 detects the rotation angles of the joints 31a to 31c at the time of detecting the first protrusion 33 (for example, the point E).

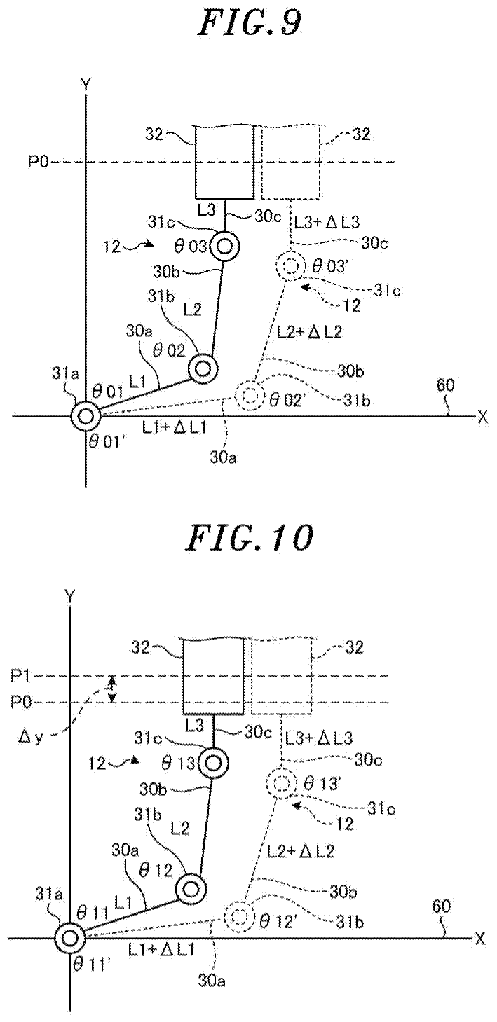

FIG. 9 shows an example of the rotation angles of the joints 31 of the robot arm 12 according to the embodiment. FIG. 9 shows the rotation angles of the joints 31 in a non-expansion state where the process chamber 13 is not expanded. In FIG. 9, the robot arm 12 having the arms 30 that are not expanded is schematically indicated by a solid line, and the robot arm 12 having the arms 30 that are expanded is schematically indicated by a dashed line. The rotation angles of the joints 31 of the robot arm 12 in a state where the arms 30 are not expanded are set to θ01 to θ03, and the lengths of the arms 30 that are not expanded are set to be L1 to L3. Further, the expansion amounts in the length direction of the arms 30 of the robot arm 12 in a state where the arms 30 are expanded are set to ΔL1 to ΔL3, and the rotation angles of the joints 31 of the robot arm 12 are set to θ01′ to θ03′. In this case, a distance P0 of the detection position of the sensor 22 in the Y-axis direction can be expressed by the following Eq. (6).

$$P 0 = L 1 \cdot sin θ01 + L 2 \cdot sin θ02 + ( L 3 + LFE ) \cdot sin θ03 = ( L 1 + Δ L 1 ) \cdot sin {θ01}^{′} + ( L 2 + Δ L 2 ) \cdot sin {θ02}^{′} + ( L 3 + Δ L 3 + LFE ) \cdot sin {θ03}^{′} \qquad ( 6 )$$

FIG. 10 shows an example of the rotation angles of the joints 31 of the robot arm 12 according to the embodiment. FIG. 10 shows the rotation angles of the joints 31 in an expansion state where the process chamber 13 is expanded. In FIG. 10, the robot arm 12 having the arms 30 that are not expanded is schematically indicated by a solid line, and the robot arm 12 having the arms 30 that are expanded is schematically indicated by a dashed line. The rotation angles of the joints 31 of the robot arm 12 in a state where the arms 30 are not expanded are set to θ11 to θ13. Further, the expansion amounts in the length directions of the arms 30 of the robot arm 12 in a state where the arms 30 are not expanded are set to ΔL1 to ΔL3, and the rotation angles of the joints 31 of the robot arm 12 are set to θ11′ to θ13′. In this case, a distance P1 of the detection position of the sensor 22 in the Y-axis direction can be expressed by following Eq. (7).

$$P 1 = L 1 \cdot sin θ11 + L 2 \cdot sin θ12 + ( L 3 - LFE ) \cdot sin θ13 = ( L 1 + Δ L 1 ) \cdot sin {θ11}^{′} + ( L 2 + Δ L 2 ) \cdot sin {θ12}^{′} + ( L 3 + Δ L 3 + LFE ) \cdot sin {θ13}^{′} \qquad ( 7 )$$

In this case, the expansion amounts (P1−P0) of the process chamber 13 can be expressed by following Eq. (8) from Eqs. (6) and (7).

$$P 1 - P 0 = L 1 \cdot sin θ11 + L 2 \cdot sin θ12 + ( L 3 - LFE ) \cdot sin θ13 - \{ L 1 \cdot sin Θ01 + L 2 \cdot sin θ02 + ( L 3 + LFR ) \cdot sin θ03 \} = ( L 1 + Δ L 1 ) \cdot sin {θ11}^{′} + ( L 2 + Δ L 2 ) \cdot sin {θ12}^{′} + ( L 3 + Δ L 3 + LFE ) \cdot sin {θ13}^{′} - \{ ( L 1 + Δ L 1 ) \cdot sin {θ01}^{′} + ( L 2 + Δ L 2 ) \cdot sin {θ02}^{′} + ( L 3 + Δ L 3 + LFE ) \cdot sin {θ03}^{′} \} \qquad ( 8 )$$

The distance P0 of the detection position of the sensor 22 in the Y-axis direction is determined from the actual measurement of the processing system 1 and the design data of the processing system 1. The distance P0 may be calculated from the lengths L1 to L3 of the arms 30 that are not expanded and the rotation angles θ01 to θ03 of the joints 31 using Eq. (6).

In present embodiment, the expansion amounts ΔL1 to ΔL3 of the arms 30 can be calculated. When the distance P0 is determined, the expansion amounts (P1−P0) of the process chamber 13 can be calculated by obtaining the distance P1 of the detection position of the sensor 22 in the Y-axis direction using Eq. (7).

The calculator 111 calculates the expansion amount of the process chamber 13 based on the lengths L1 to L3 of the arms 30 that are not expanded, the calculated expansion amounts ΔL1 to ΔL3 of the arms 30, and the rotation angles θ11′ to θ13′ of the joints 31 detected by the detector 110. For example, the calculator 111 uses Eq. (7) to calculate the distance P1 from the lengths L1 to L3 of the arms 30 that are not expanded, the calculated expansion amounts ΔL1 to ΔL3 of the arms 30, and the rotation angles θ11′ to θ13′ of the joints 31 detected by the detector 110. Then, the calculator 111 subtracts the distance P1 from the distance P0 to calculate the expansion amount (P1−P0) of the process chamber 13.

As described above, in accordance with the present embodiment, even when the arms 30 are expanded, the expansion amount of the process chamber 13 can be calculated.

### <Expansion Amount Calculation Method>

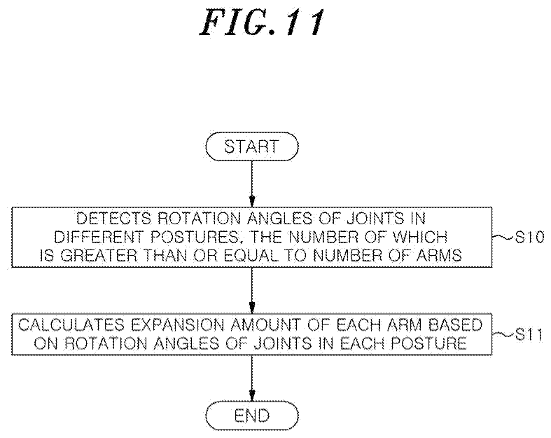

Next, an example of control flow of an expansion amount calculation method in which the processing system 1 calculates the expansion amounts of the arms 30 of the robot arm 12 will be described. FIG. 11 explains an example of the control flow of the expansion amount calculation method according to the embodiment.

The detector 110 detects the rotation angles of the joints 31 in different postures, the number of which is greater than or equal to the number of arms 30 of the robot arm 12 (step S10). For example, the controller 100 moves the robot arm 12 such that the protrusions 33 disposed at the fork 32 pass through the arrangement position of the sensor 20a. The detector 110 detects the rotation angles of the joints 31 at the points E, G, and I where the protrusions 33 are detected by the sensor 20a.

The calculator 111 calculates the expansion amounts of the arms 30 based on the rotation angles of the joints 31 in each detected posture (step S11), and the processing is ended. For example, the calculator 111 applies, to Eq. (5), the extended/contracted distance Y of the robot arm 12 and the rotation angles θ1′ to θ3′ of the joints 31 detected by the detector 110 in each posture. Then, the calculator 111 calculates the expansion amounts ΔL1 to ΔL3 by solving the equation by way of using the expansion amounts ΔL1 to ΔL3 in Eq. (5) for each posture as unknown values.

As described above, the processing system 1 of the present embodiment includes the robot arm 12 (articulated arm), the detector 110, and the calculator 111. The robot arm 12 in which the arms 30 are connected by the rotatable joints 31 can be extended and contracted by rotating the joints 31. The detector 110 detects the rotation angles of the joints 31 of the robot arm 12 in different postures, the number of which is greater than or equal to the number of arms 30 of the robot arm 12. The calculator 111 calculates the expansion amounts of the arms 30 based on the rotation angles of the joints 31 in each posture detected by the detector 110. Accordingly, the processing system 1 of the present embodiment can obtain the expansion amount of each of the arms 30.

Further, the calculator 111 calculates the expansion amounts of the arms 30 from the lengths L1 to L3 of the arms 30 that are not expanded, the extended/contracted distance Y of the robot arm 12 in each posture, and the rotation angles θ1′ to θ3′ of the joints 31 in each posture detected by the detector 110. Accordingly, the processing system 1 of the present embodiment can calculate the expansion amount of each of the arms 30.

Further, the calculator 111 calculates the expansion amount of each of the arms 30 by solving the relational expression (Eq. (5)) indicating relationship between the extended/contracted distance of the robot arm 12, the lengths L1 to L3 of the arms 30 that are not expanded, the rotation angles θ1′ to θ3′ of the joints 31, and the expansion amounts ΔL1 to ΔL3 of the arms 30 in each posture, by way of using the expansion amounts of the arms 30 as unknown values and applying the extended/contracted distance of the robot arm 12 and the rotation angles of the joints 31 detected by the detector 110 in each posture to the relational expression. Accordingly, the processing system 1 of the present embodiment can calculate the expansion amount of each of the arms 30.

Further, the calculator 111 calculates the expansion amount of each of the arms 30 by applying the rotation angles of the joints 31 in each posture detected by the detector 110 to the relational expression for calculating the expansion amounts of the arms 30 from the extended/contracted distance of the robot arm 12 in each posture, the lengths of the arms 30 that are not expanded, and the rotation angles of the joints 31 in each posture. In this case as well, the processing system 1 of the present embodiment can calculate the expansion amount of each of the arms 30.

Further, the different postures are postures in which the robot arm 12 is extended/contracted by different distances. Therefore, the rotation angles of the joints 31 are changed in each posture. Accordingly, the processing system 1 of the present embodiment can accurately calculate the expansion amounts of the arms 30 from the rotation angles of the joints 31 in each posture.

While the embodiments of the present disclosure have been described, it should be noted that the embodiments of the present disclosure are illustrative in all respects and are not restrictive. The above-described embodiments may be omitted, replaced, or changed in various forms without departing from the scope of the appended claims and the gist thereof.

For example, in the above embodiment, the case where each of the sensor 20 and the sensor 22 has the light source 21a and the light receiving sensor 21b, and the arrival of the robot arm 12 is detected when the light from the light source 21a is blocked has been described. However, the present disclosure is not limited thereto. Any method may be used for the sensor 20 and the sensor 22 as long as the arrival of the robot arm 12 can be detected.

Further, in the above embodiment, as shown in FIG. 2, the case where one support portion 32a of the fork 32 is provided with the three rectangular protrusions 33 protruding in the horizontal direction so that the positions can be detected by the sensor 20 been described as an example. However, the present disclosure is not limited thereto. The fork 32 may have any shape as long as the extended/contracted position can be detected by the sensor 20. For example, in the fork 32, the protrusions 33 may be disposed at each of the two support portions 32a. The protrusions 33 may be symmetrically installed at the fork 32.

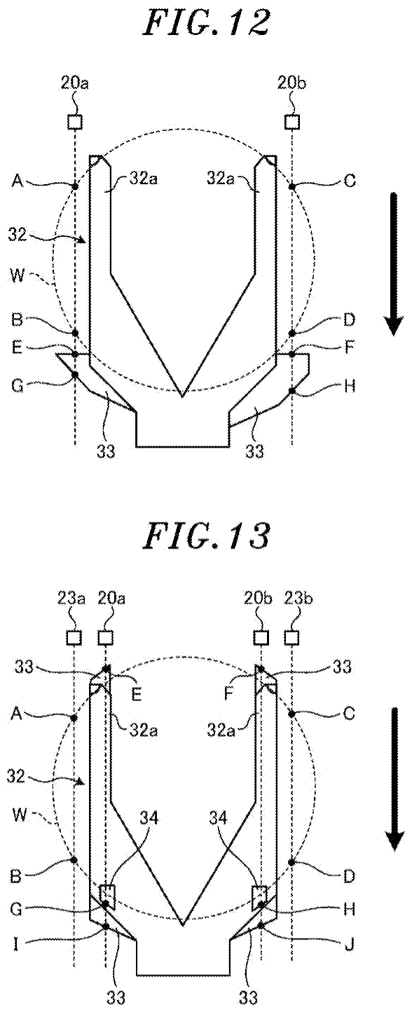

FIG. 12 shows another example of the shape of the fork 32 according to the embodiment. The fork 32 has the two Y-shaped support portions 32a branched toward the tip end side. The two support portions 32a of the fork 32 are provided with the protrusions 33 protruding outward in the horizontal direction near the end portions connected to the arms 30c. The two protrusions 33 disposed at the two support portions 32a have a partially symmetrical shape. For example, the two protrusions 33 disposed at the two support portions 32a are formed to be symmetrical on the tip end side of the fork 32. The two protrusions 33 are formed to be perpendicular to the tip end side of the fork 32 on the tip end side of the fork 32, and are formed obliquely on the base end side of the fork 32 such that the width thereof gradually decreases toward the base end side of the fork 32. One of the two protrusions 33 is formed to extend toward the base end side compared to the other protrusion 33. In FIG. 12, the substrate W placed on the fork 32 is indicated by a dotted line. Further, in FIG. 12, the position where the robot arm 12 passes through the sensing areas of the sensors 20a and 20b at the time of taking out the substrate W from the load-lock chamber 14 using the robot arm 12 is indicated by a dotted line. When the substrate W passes through the sensing area, the four points A to D are detected by the sensors 20a and 20b. The controller 100 specifies the center of the circle passing through at least three of the points A to D as the center position O of the substrate W. When the protrusions 33 of the fork 32 pass through the sensing areas, the four points E to H are detected by the sensors 20a and 20b. The calculator 111 calculates the expansion amounts of the arms 30 based on the rotation angles of the joints 31 in each detected posture. For example, the expansion amount of each of the arms 30 are calculated from the rotation angles of the joints 31 at the average distance Y at the time of detecting the points E and F, the distance Y at the time of detecting the point G, and the distance Y at the time of detecting the point H. Accordingly, the processing system 1 of the present embodiment can obtain the expansion amount of each of the arms 30. Further, when the substrate W is taken out from the load-lock chamber 14 by the robot arm 12, the center position O of the substrate W and the expansion amounts of the arms 30 can be calculated at the same time, and the transfer position of the substrate W to the placing table can be corrected.

FIG. 13 shows another example of the shape of the fork 32 according to the embodiment. The fork 32 has the two Y-shaped support portions 32a branched on the tip end side. The two support portions 32a of the fork 32 are symmetrically formed. The fork 32 has slits 34 that are symmetrically formed near the branch portion where the two support portions 32a are branched. In the fork 32, the protrusions 33 protruding horizontally toward the tip end side are disposed at the tip ends of the two support portions 32a. Further, the fork 32 is provided with the protrusions 33 extending from the two support portions 32a toward the base end side at the branch portion of the two support portions 32a. In FIG. 13, the substrate W placed on the fork 32 is indicated by a dotted line. The fork 32 is larger than the substrate W, and the protrusions 33 on the tip end sides of the two support portions 32a pass through the substrate W and are exposed. The sensors 20a and 20b are arranged at an interval corresponding to the gap between the two support portions 32a. Further, sensors 23a and 23b having the same configuration as that of the sensors 20a and 20b are disposed at the outer sides of the sensors 20a and 20b. In FIG. 13, the substrate W placed on the fork 32 is indicated by a dotted line. Further, in FIG. 13, the positions where the robot arm 12 passes through the sensing areas of the sensors 20a, 20b, 23a, and 23b at the time of taking out the substrate W from the load-lock chamber 14 are indicated by dotted lines. The substrate W passes through the sensing areas of the sensors 23a and 23b. When the substrate W passes through the sensing areas, the four points A to D are detected by the sensors 23a and 23b. The controller 100 specifies the center of the circle passing through at least three points among the points A to D as the center position O of the substrate W. The tip ends of the fork 32, the slit 34, or the end portion pass through the sensing areas of the sensors 20a and 20b. When the tip end of the fork 32, the slit 34, or the end portion pass through the sensing areas, six points E to J are detected by the sensors 20a and 20b. The calculator 111 calculates the expansion amounts of the arms 30 based on the rotation angles of the joints 31 in each detected posture. For example, the expansion amounts of the arms 30 are calculated from the rotation angles of the joints 31 at the average distance Y at the time of detecting the points E and F, the average distance Y at the time of detecting the points G and H, and the average distance Y at the time of detecting the points I and J. Accordingly, the processing system 1 of the present embodiment can obtain the expansion amounts of the arms 30. The center position O of the substrate W and the expansion amounts of the arms 30 can be calculated at the same time, and the transfer position of the substrate W to the placing table can be corrected.

Although the above embodiment has described the case where the substrate W is a semiconductor wafer, the present disclosure is not limited thereto. The substrate W may be any substrate such as a glass substrate or the like.

Although the above embodiment has described the case where the sensor 20 (the sensors 20a and 20b) is disposed near the connection portion between the vacuum transfer chamber 11 and the load-lock chamber 14, and the rotation angles of the joints of the robot arm 12 are detected when the protrusions 33 disposed at the fork 32 pass through the arrangement position of the sensor 20 as an example. However, the present disclosure is not limited thereto. FIG. 15 shows another example of the processing system main body 10 according to the embodiment. In FIG. 15, like reference numerals will be used for like parts as those of FIG. 1, and redundant description thereof will be omitted. In the processing system main body 10 shown in FIG. 15, a sensor 24 (sensors 24a and 24b) that is the same as the sensor 20 (the sensors 20a and 20b) is disposed near the connection portion between the vacuum transfer chamber 11 and each process chamber 13. When the robot arm 12 load/unloads the substrate W into/from each process chamber 13, the protrusions 33 disposed at the fork 32 pass through the arrangement positions of the sensors 24a and 24b. The controller 100 may detect the rotation angles of the joints of the robot arm 12 when the protrusions 33 disposed at the fork 32 pass through the arrangement position of the sensor 20, and may calculate the expansion amounts of the arms 30 based on the detected rotation angles of the joints.

### DESCRIPTION OF REFERENCE NUMERALS

1: processing system
11: vacuum transfer chamber
12: robot arm
13: process chamber
14: load-lock chamber
15: loader module
20: sensor
30, 30a to 30c: arm
31, 31a to 31c: joint
32: fork
32a: support portion
33: protrusion
100: controller
101: process controller
102: user interface
103: storage part
110: detector
111: calculator
W: substrate

1. A transfer device comprising:
an articulated arm including a plurality of arms connected by rotatable joints, the articulated arm configured to be extensible and contractible by rotating the rotatable joints;
a detector configured to detect rotation angles of the rotatable joints of the articulated arm in different postures, a number of which is greater than or equal to a number of the plurality of arms of the articulated arm; and
a calculator configured to calculate an expansion amount of each of the plurality of arms based on the rotation angles of the rotatable joints in each posture detected by the detector.

2. The transfer device of claim 1, wherein the calculator calculates the expansion amount of each of the plurality of arms based on lengths of the plurality of arms in a non-expansion state where the plurality of arms are not expanded, an extended/contracted distance of the articulated arm in each posture in the non-expansion state, and the rotation angles of the rotatable joints in each posture detected by the detector.

3. The transfer device of claim 2, wherein the calculator calculates the expansion amount of each of the plurality of arms by solving a relational equation that indicates a relationship between the extended/contracted distance of the articulated arm, the lengths of the plurality of arms in the non-expansion state, the rotation angles of the rotatable joints, and the expansion amounts of the plurality of arms, by way of applying the extended/contracted distance of the articulated arm and the rotation angles of the rotatable joints detected by the detector in each posture to the equation and using the expansion amounts of the plurality of arms in the relational equation for each posture as unknown values.

4. The transfer device of claim 2, wherein the calculator calculates the expansion amount of each of the plurality of arms by applying the rotation angles of the rotatable joints in each posture detected by the detector to a relational equation for calculating the expansion amounts of the plurality of arms from the extended/contracted distance of the articulated arm in each posture, the lengths of the plurality of arms in the non-expansion state, and the rotation angles of the rotatable joints in each posture.

5. The transfer device of claim 1, wherein the different postures are postures in which the articulated arm is extended/contracted by different distances.

6. The transfer device of claim 1, wherein the detector detects the rotation angles of the rotatable joints at a time of detecting the articulated arm by a sensor provided at a chamber for performing substrate processing, and
the calculator calculates an expansion amount of the chamber based on lengths of the plurality of arms in a non-expansion state, the calculated expansion amounts of the plurality of arms, and the rotation angles of the rotatable joints detected by the detector.

7. The transfer device of claim 1, further comprising:
a transfer controller configured to correct a transfer position of the articulated arm based on the expansion amounts of the plurality of arms calculated by the calculator.

8. An expansion amount calculation method comprising:
detecting rotation angles of rotatable joints of an articulated arm including a plurality of arms connected by the rotatable joints and configured to be extensible and contractible by rotating the rotatable joints in different postures, a number of which is greater than or equal to a number of the plurality of arms of the articulated arm; and
calculating an expansion amount of each of the plurality of arms based on the rotation angles of the rotatable joints in each detected posture.
